(19) United States
(12) Patent Application Publication
(10) Pub. No.: US 2019/0276310 A1
(43) Pub. Date: Sep. 12, 2019

(54) METHOD FOR PREPARING HEXAGONAL BORON NITRIDE BY TEMPLATING

(71) Applicant: ROGERS CORPORATION, Chandler, AZ (US)

(72) Inventors: Lei Liu, Suzhou (CN); Jian Zhang, Suzhou (CN); Yang Zhong, Shanghai (CN); Xinhe Tang, Bavaria (DE); Karsten Schmidt, Eschenbach (DE)

(21) Appl. No.: 16/293,719

(22) Filed: Mar. 6, 2019

(30) Foreign Application Priority Data
Mar. 7, 2018 (CN) 201810186629.8

(51) Int. Cl. C01B 21/064; C09K 5/14; C08K 7/04; C08K 3/38; C08J 9/00; F28F 21/04

(52) U.S. Cl. CPC C01B 21/0645; H05K 1/0203; C08K 7/04; C08K 3/38; C08J 9/0076; F28F 21/04; C01P 2002/72; C01P 2004/03; C01P 2006/32; C01P 2002/76; C01P 2004/16; C08K 2201/011; C08K 2201/001; C08K 2003/385; C08J 2205/06; C09K 5/14

(57) ABSTRACT

In an aspect, a method for preparing hexagonal boron nitride comprises mixing a boron compound and a carbon template in an organic solvent; removing the organic solvent to provide a dried mixture of the boron compound and the carbon template; exposing the dried mixture to a nitrogen-containing gas under conditions effective to provide a crude product comprising hexagonal boron nitride; removing the carbon template from the crude product to provide the hexagonal boron nitride.

### CROSS-REFERENCE TO RELATED APPLICATION

This application claims the benefit of Chinese Patent Application Serial No. 201810186629.8 filed Mar. 7, 2019. The related application is incorporated herein in its entirety by reference.

### BACKGROUND

Carbon has applications in many important fields such as high-energy battery materials, sealing materials, biomedicine, phase-change heat storage materials, and environmental protection, in part, due to its ability to form hexagonal crystalline structures. The crystal structure of hexagonal boron nitride is similar to hexagonal carbon, both having a hexagonal crystal system and a laminar structure with multiple layers being joined by means of molecular bonds. Hexagonal boron nitride has a very good lubricating effect and is often referred to as “white graphite.” Hexagonal boron nitride not only has a structure and properties similar to those of graphite material, but also has some excellent properties that hexagonal carbon lacks, such as electrical insulation, corrosion resistance and good high-temperature performance. If hexagonal boron nitride with structural features similar to those of hexagonal carbon could be prepared, it would have broad application prospects in fields such as electronics, machinery, environmental protection, and atomic energy. However, the molecular bonds joining layers of hexagonal boron nitride are far stronger than the molecular bonds joining layers of hexagonal carbon, making it extremely difficult to open up the molecular bonds joining layers of hexagonal boron nitride using methods commonly used to prepare hexagonal carbon, namely intercalation, washing in water, drying, and high-temperature expansion.

A method for successfully preparing a hexagonal boron nitride is therefore desired.

### BRIEF SUMMARY

Disclosed herein is a method of preparing a hexagonal boron nitride and the hexagonal boron nitride made therefrom.

In an aspect, a method for preparing hexagonal boron nitride comprises mixing a boron compound and a carbon template in an organic solvent; wherein the carbon template comprises a plurality of carbon fibers, a plurality of carbon nanotubes, activated carbon, a plurality of graphite films, a plurality of graphene sheets, or a combination comprising at least one of the foregoing; removing the organic solvent to provide a dried mixture of the boron compound and the carbon template; exposing the dried mixture to a nitrogen-containing gas under conditions effective to provide a crude product comprising hexagonal boron nitride; removing the carbon template from the crude product to provide the hexagonal boron nitride in the form of a plurality of boron nitride fibers, a plurality of boron nitride nanotubes, an activated boron nitride, a plurality of boron nitride films, a plurality of boron nitride sheet, or a combination comprising at least one of the foregoing.

Also disclosed herein is a hexagonal boron nitride.

Further disclosed is a composite material comprising the hexagonal boron nitride and a polymer.

Further disclosed is a thermal management assembly comprising the hexagonal boron nitride.

Further still is disclosed an article comprising the hexagonal boron nitride.

The above described and other features are exemplified by the following figures, detailed description, and claims.

### BRIEF DESCRIPTION OF THE DRAWINGS

The following Figures are exemplary aspects, which are provided to illustrate the method of making the hexagonal boron nitride and the hexagonal boron nitride made therefrom. The figures are illustrative of the examples, which are not intended to limit devices made in accordance with the disclosure to the materials, conditions, or process parameters set forth herein.

FIG. 1 is a graphical illustration of the X-ray diffraction spectrum for the hexagonal boron nitride synthesized in Example 1;

FIG. 2 is a scanning electron microscope (SEM) image of the carbon fibers used as the template in Example 1; and

FIG. 3 is a scanning electron microscope image of the hollow, hexagonal boron nitride fibers synthesized in Example 1.

### DETAILED DESCRIPTION

It was surprisingly discovered that hexagonal boron nitride could be prepared by templating the hexagonal boron nitride off of a carbon template. Specifically, the method comprises mixing a boron compound and a carbon template in an organic solvent; removing the organic solvent to provide a dried mixture of the boron compound and the carbon template; exposing the dried mixture to a nitrogen-containing gas under conditions effective to provide a crude product comprising hexagonal boron nitride; and removing the carbon template from the crude product to provide the hexagonal boron nitride. Due to the use of the carbon template as a direct template for the hexagonal structure of the boron nitride, the present method can beneficially provide the boron nitride morphology that copies of the morphology of the carbon template, allowing for different morphologies to be formed, for example, at least one of particulate, tube, or nanosheet morphologies.

The method has the benefit in that it can be used to manufacture large quantities of hexagonal boron nitride having a high purity, for example, of 95 to 100 weight percent (wt %), or 99 to 100 wt % based on a total weight of the hexagonal boron nitride product formed by the present method. The method can be environmentally friendly as it can use environmentally friendly boron and carbon sources and, as the carbon source of graphite is easy to degrade, acid washing and water washing steps can be avoided.

The method comprises mixing a boron compound and a carbon template in an organic solvent. The boron compound can comprise any boron-containing compound that produces boron nitride under the carbothermal reduction and nitridation conditions described below. Oxygen-containing boron compounds can be used, including various salts and hydrates. The oxygen-containing boron compound can comprise an amine pentaborate, a borate ester, borax (Na₂B₄O₇·10H₂O or Na₂[B₄O₅(OH)₄]·8H₂O), boric acid (H₃BO₃) or a salt thereof, pyroboric acid (B₄H₂O₇) or a salt thereof, tetraboric acid (H₂B₄O₇) or a salt thereof, boron oxide (B₂O₃), or a combination comprising one or more of the foregoing. The amine pentaborate includes any amine salt, for example, an amine salt of at least one of the formula B₅O₈⁻NR₄⁺ or B₅O₆(OH)₄⁻NR₄⁺ wherein each R can the same or different, and is hydrogen or an organic ligand, for example, a C₁₋₈ alkyl group or a C₄₋₈ cycloalkyl group Ammonium pentaborate (B₅O₈⁻NR₄⁺) can be used. The borate ester can be any ester of boric acid, e.g., an ester of the formula B(OR)₃ wherein each R can the same or different, and is an organic ligand, for example, a C₁₋₁₂ alkyl group organic ligand, for example, a C₁₋₁₂ alkyl group. The corresponding salts of the various acids can have any counterion, for example, ammonium, phosphonium, an alkali metal, an alkaline earth metal, or a combination comprising one or more of the foregoing. The boron compound can comprise boric acid, pyroboric acid, boron oxide, or a combination comprising one or more of the foregoing. The boron compound can comprise boron oxide.

The carbon template can comprise carbon fibers, carbon nanotubes, activated carbon, graphite films, graphene sheets, or a combination comprising at least one of the foregoing. The carbon fibers can have an average diameter of 10 nanometers to 50 micrometers, or 100 nanometers to 10 micrometers, or 200 nanometers to 1 micrometer. The carbon fibers can have an average ratio of the length to the diameter of greater than or equal to 2, or 10 to 1,000, or 15 to 100. The carbon fibers can be solid, i.e., the can be free of a hollow center. The diameter and length of the carbon fibers can be measured via image analysis of scanning electron microscopy images.

The carbon nanotubes can have an average diameter of 1 to 200 nanometers, or 5 to 100 nanometers. The carbon nanotubes can have an average ratio of the length to the diameter of greater than or equal to 2, or 10 to 1,000, or 15 to 100. The carbon nanotubes can be hollow. The carbon nanotubes can comprise single wall nanotubes. The carbon nanotubes can comprise multiwall nanotubes. The diameter and length of the carbon nanotubes can be measured via image analysis of scanning electron microscopy images.

The activated carbon can comprise a microcrystalline, nongraphitic form of carbon that has been processed to increase internal porosity. The activated carbon can have a surface area of 500 to 2,500 meters squared per gram (m²/g). As used herein, the surface area can be determined using the Bmnauer-Emmett-Teller method.

The graphite film can comprise multiple layers of carbon graphene sheets, where the graphene sheets are single-carbon atom thick sheets where the carbon atoms are arranged in a hexagonal array.

The carbon template can comprise a surface treated carbon template to increase the ability of the boron compound to adsorb onto the carbon template. For example, the carbon template can be surface treated to comprise one or both of hydroxyl and carboxyl functional groups.

The organic solvent can comprise a C₁₋₆ alkanol (for example, ethanol, methanol, propanol, butanol, pentanol, or hexanol), a polyol (for example, glycerin, pentaerythritol, ethylene glycol, or sucrose), a polyether (for example, polyethylene glycol or polypropylene glycol), or a combination comprising one or more of the foregoing. The organic solvent can comprise ethanol, methanol, glycerin, polyethylene glycol, or a combination comprising one or more of the foregoing. The mixture can comprise 5 to 200 milliliters (mL), or 5 to 25 mL, or 5 to 15 mL, or 25 to 200 mL of the organic solvent per 1 gram (g) of the total of the boron compound and the carbon template.

The mixture can further comprise a dispersant to improve dispersion of the boron compound and the carbon template. The type of dispersant can depend on the type of boron compound and the type of carbon template. The dispersant can be a surfactant. The surfactant can be anionic, nonionic, cationic, or zwitterionic. The surfactant can be anionic.

Among the anionic surfactants that can be used are the alkali metal, alkaline earth metal. ammonium and amine salts of organic sulfuric reaction products having in their molecular structure a C₈₋₃₆, or C₈₋₂₂, alkyl or acyl group and a sulfonic acid or sulfuric acid ester group. The dispersant can comprise sodium dodecyl sulfate, sodium lauryl sulfate, sodium laureth sulfate, sodium dioctyl sulfosuccinate, sodium dihexyl sulfosuccinate, perfluorooctane sulfonate, perfluorooctanoic acid, sodium dodecylbenzenesulfonate, or a combination comprising at least one of the foregoing. The dispersant can comprise sodium dodecyl sulfate.

Nonionic surfactants can be used and can include a C₈₋₂₂ aliphatic alcohol ethoxylate having about 1 to about 25 moles of ethylene oxide and having have a narrow homolog distribution of the ethylene oxide (“narrow range ethoxylates”) or a broad homolog distribution of the ethylene oxide (“broad range ethoxylates”); for example, a C₁₀₋₂₀ aliphatic alcohol ethoxylate having about 2 to about 18 moles of ethylene oxide. Examples of commercially available nonionic surfactants of this type are TERGITOL 15-S-9 (a condensation product of C₁₁₋₁₅ linear secondary alcohol with 9 moles ethylene oxide), TERGITOL 24-L-NMW (a condensation product of C₁₂₋₁₄ linear primary alcohol with 6 moles of ethylene oxide) with a narrow molecular weight distribution, from Dow. Other nonionic surfactants that can be used include polyethylene, polypropylene, or polybutylene oxide condensates of C₆₋₁₂ alkyl phenols, for example, compounds having 4 to 25 moles of ethylene oxide per mole of C₆₋₁₂ alkylphenol, for example, 5 to 18 moles of ethylene oxide per mole of C₆₋₁₂ alkylphenol. Commercially available surfactants of this type include Igepal CO-630, TRITON X-45, X-114, X-100 and X102, TERGITOL TMN-10, TERGITOL TMN-100X, and TERGITOL TMN-6 (all polyethoxylated 2,6,8-trimethyl-nonylphenols or mixtures thereof) from Dow.

The mixture can comprise 0.01 to 10 wt % or 0.1 to 5 wt % of the dispersant, based on the total weight of the boron compound and the carbon template. The mixture can have a molar ratio of carbon template to the boron compound of 1:0.2 to 1:2.

The mixing can occur at a temperature of 0 to 60 degrees Celsius (° C.), or 10 to 50° C., or 15 to 35° C. The mixing can occur for 0.5 to 10 hours, or 0.5 to 5 hours, or 0.5 to 1.5 hours, or 2 hours to 10 hours, or 5 to 9 hours.

The mixing can comprise wet ball mixing. The mixing can comprise stirring, for example, with a magnetic stir bar. The mixing can comprise ultrasonically vibrating the mixture. The mixture can be ultrasonically vibrated for 1 to 5 hours, or 1 to 3 hours. Using a method such as stirring for greater than or equal to 2 hours, ultrasonically vibrating during mixing, and wet ball mixing can disrupt the particulate morphology, for example, of the particulate graphite, increasing the surface area available for templating and can result in the formation of graphite nanosheets.

After the mixing, the organic solvent can be removed to form a dried mixture of the carbon template and the boron compound. The dried mixture can be formed by at least one of heating the mixture, applying a vacuum pressure to the mixture, or freeze-drying the mixture. Freeze-drying the mixture can have the benefit of reducing the amount of boron compound separated from the carbon template during the removal of the organic solvent. The dry mixture can comprise less than or equal to 1 mL, or 0 to 0.1 mL of the organic solvent per 1 g of the total of the boron compound and the carbon template.

The dried mixture is then exposed to conditions effective to form the hexagonal boron nitride. Without being bound by theory, it is believed that the effective conditions are a carbothermal reduction process. Starting with boron oxide, such a carbothermal reduction and nitridation reaction can proceed in accordance with equation (1).

B₂O₃+3C+N₂→2BN+3CO (1)

The carbothermal reduction and nitridation reaction (also referred to herein as the reaction for ease or reference) in an oxygen free environment. The carbothermal reduction and nitridation reaction can be performed on the dried mixture by flowing a nitrogen gas through the dried mixture for 1 to 10 hours to provide a crude product. The reaction time can be 1 to 15 hours, or 1 to 10 hours, or 3 to 10 hours, or 5 to 15 hours. A flow rate of the nitrogen gas can be 40 to 1,000 milliliters per minute (ml/min), or 60 to 200 mL/min during the exposing.

The reaction can be performed in an oxygen free environment. For example, the oxygen free environment can comprise less than or equal to 100 parts per million (ppm), or less than or equal to 10 ppm by volume of oxygen. The reaction can occur in a reaction chamber, for example, in a crucible (for example, a graphite crucible or a clay crucible). The dried mixture can be spread out to form a thin layer in the reaction chamber. The thin layer can have a layer thickness of less than or equal to 1 millimeters (mm), or 0.1 to 0.5 mm The reaction chamber can be located in a furnace, for example, in a tubular furnace during the exposing.

The exposing can occur at an increased temperature, for example, at a temperature of 400 to 1,600° C., or 600 to 1,500° C. The use of a suitable heating system can prevent the boron compound from undergoing reactions other than the carbothermal reduction and nitridation reaction, thereby avoiding a reduced output of hexagonal boron nitride. The increased temperature can be achieved in one or more, or two or more, or three or more heating stages. The heating stages can increase the temperature at a rate of 1 to 15 degree Celsius per minute (° C./min), or 5 to 12° C./min If a single heating stage is used, the heating rate can be less than or equal to 5° C./min, or less than or equal to 1° C./min. After each heating stage, the temperature can be maintained for an amount of time, for example, of 1 to 5 hours, or 1 to 3 hours before the subsequent heating stage is initiated.

An exemplary heating can comprise heating the dry mixture to a first temperature of 100 to 500° C. at a rate of 3 to 10° C./min; maintaining the first temperature for 0.5 to 3 hours; heating to a second temperature of 700 to 1,100° C. at a rate of 3 to 10° C./min; maintaining the second temperature for 0.5 to 3 hours; heating to a third temperature of 1,200 to 1,700° C. at a rate of 3 to 10° C./min; and maintaining the third temperature for 0.5 to 3 hours.

After the reaction, the carbon template can be removed from the crude product to provide the hexagonal boron nitride, for example, by heating. The heating to remove the carbon template can occur in oxygen or air. The heating to remove the carbon template can comprise reacting with oxygen in the boron compound if present, for example, if the boron compound comprises boron oxide. The heating to remove the carbon template can occur at a temperature of 500 to 1,000° C., or 600 to 900° C., or 700 to 800° C. The heating to remove the carbon template can occur for a time period of 1 to 15 hours, or 3 to 10 hours, or 3 to 8 hours.

Depending on the carbon template used, the resultant hexagonal boron nitride can reflect the form of the carbon template. For example, the hexagonal boron nitride be in the form of a plurality of boron nitride fibers, a plurality of boron nitride nanotubes, an activated boron nitride, a plurality of boron nitride films, a plurality of boron nitride sheet, or a combination comprising at least one of the foregoing. The resultant form of the hexagonal boron nitride can have lateral (for example, diameters) dimensions that are larger than that of the respective carbon template. This increase in the lateral dimension can arise as the boron atoms are templating off of the carbon atoms and are not directly replacing them. The boron nitride film can comprise multiple layers of boron nitride sheets, where the boron nitride sheets are single-atom thick sheets where the boron nitride atoms are arranged in a hexagonal array.

The hexagonal boron nitride can have a thermal conductivity, according to ASTM E1225-13, of 1 to 2,000 watts per meter-Kelvin (W/m·K) or more, or 1 to 2,000 W/m·K, or 10 to 1,800 W/m·K, or 100 to 1,600 W/m·K, or 1,500 to 2,000 W/m·K. The hexagonal boron nitride can also have an electrical resistivity of 5 to 15 ohm-centimeters (Ω-cm) at room temperature (for example, at 25° C.), or 8 to 12 Ω-cm, a dielectric constant of 3 to 4, for example 3.01 to 3.36 at room temperature at 5.75×10⁹ hertz (Hz), and a loss tangent of 0.0001 to 0.001, or 0.0003 to 0.0008 at room temperature at 5.75×10⁹ Hz, or 0.0003 to 0.0008.

The present method can result in an efficient, low-cost preparation of hexagonal boron nitride to open up a new shortcut for further improvement of the quality and output of two-dimensional hexagonal boron nitride nanosheets or three-dimensional hexagonal boron nitride particles that can lay a strong foundation for the manufacture of an isotropic, insulating composite material with high thermal conductivity. The composite material can comprise the hexagonal boron nitride and a polymer. The polymer can comprise a thermoset polymer or a thermoplastic polymer. The polymer can be a foam.

Thermoset polymers are derived from thermosetting monomers or prepolymers (resins) that can irreversibly harden and become insoluble with polymerization or cure, which can be induced by heat or exposure to radiation (e.g., ultraviolet light, visible light, infrared light, or electron beam (e-beam) radiation). Thermoset polymers include alkyds, bismaleimide polymers, bismaleimide triazine polymers, cyanate ester polymers, benzocyclobutene polymers, benzoxazine polymers, diallyl phthalate polymers, epoxies, hydroxymethylfuran polymers, melamine-formaldehyde polymers, phenolics (including phenol-formaldehyde polymers such as novolacs or resoles), benzoxazines, polydienes such as polybutadienes (including homopolymers or copolymers thereof, e.g., poly(butadiene-isoprene)), polyisocyanates, polyureas, polyurethanes, triallyl cyanurate polymers, triallyl isocyanurate polymers, certain silicone polymers, or polymerizable prepolymers (e.g., prepolymers having ethylenic unsaturation, such as unsaturated polyesters, polyimides), epoxy resins, or the like. The prepolymers can be polymerized, copolymerized, or crosslinked, e.g., with a reactive monomer such as at least one of styrene, alpha-methylstyrene, vinyltoluene, chlorostyrene, acrylic acid, (meth)acrylic acid, a (C₁₋₆ alkyl)acrylate, a (C₁₋₆ alkyl) methacrylate, acrylonitrile, vinyl acetate, allyl acetate, triallyl cyanurate, triallyl isocyanurate, or acrylamide. The weight average molecular weight of the prepolymers can be 400 to 10,000 Daltons based on polystyrene standards.

As used herein, the term “thermoplastic” refers to a material that is plastic or deformable, melts to a liquid when heated, and freezes to a brittle, glassy state when cooled sufficiently. Examples of thermoplastic polymers that can be used include cyclic olefin polymers (including polynorbornenes and copolymers containing norbornenyl units, for example, copolymers of a cyclic polymer such as norbornene and an acyclic olefin such as ethylene or propylene), fluoropolymers (e.g., poly(vinyl fluoride) (PVF), poly(vinylidene fluoride) (PVDF), fluorinated ethylene-propylene (FEP), polytetrafluoroethylene (PTFE), poly(ethylene-tetrafluoroethylene) (PETFE), perfluoroalkoxy (PFA)), polyacetals (e.g., polyoxyethylene or polyoxymethylene), poly(C₁₋₆ alkyl)acrylates, polyacrylamides (including unsubstituted or mono-N- and di-N-(C₁₋₈ alkyl)acrylamides), polyacrylonitriles, polyamides (e.g., aliphatic polyamides, polyphthalamides, or polyaramides), polyamideimides, polyanhydrides, poly(arylene ethers) (e.g., poly(phenylene ethers)), poly(arylene ether ketones) (e.g., poly(ether ether ketones) (PEEK) and poly(ether ketone ketones) (PEKK), poly(arylene ketones), poly(arylene sulfides) (e.g., poly(phenylene sulfides) (PPS)), poly(arylene sulfones) (e.g., polyethersulfones (PES), polyphenylene sulfones (PPS), or the like), polybenzothiazoles, polybenzoxazoles, polybenzimidazoles, polycarbonates (including homopolycarbonates or polycarbonate copolymers such as polycarbonate-siloxanes, polycarbonate-esters, or polycarbonate-ester-siloxanes), polyesters (e.g., polyethylene terephthalates, polybutylene terephthalates, polyarylates, or polyester copolymers such as polyester-ethers), polyetherimides (including copolymers such as polyetherimide-siloxane copolymers), polyimides (including copolymers such as polyimide-siloxane copolymers), poly(C₁₋₆ alkyl)methacrylates, polymethacrylamides (including unsubstituted or mono-N- and di-N-(C₁₋₈ alkyl)acrylamides), polyolefins (e.g., polyethylenes, such as high density polyethylene (HDPE), low density polyethylene (LDPE), or linear low density polyethylene (LLDPE), polypropylenes, or their halogenated derivatives (such as polytetrafluoroethylenes), or their copolymers, for example ethylene-alpha-olefin copolymers, polyoxadiazoles, polyoxymethylenes, polyphthalides, polysilazanes, polysiloxanes (silicones), polystyrenes (including copolymers such as acrylonitrile-butadiene-styrene (ABS) or methyl methacrylate-butadiene-styrene (MBS)), polysulfides, polysulfonamides, polysulfonates, polysulfones, polythioesters, polytriazines, polyureas, polyurethanes, vinyl polymers (including poly(vinyl alcohols), poly(vinyl esters), poly(vinyl ethers), poly(vinyl halides) (e.g., poly(vinyl fluoride)), poly(vinyl ketones), poly(vinyl nitriles), poly(vinyl thioethers), or poly(vinylidene fluorides)), or the like. A combination comprising at least one of the foregoing thermoplastic polymers can be used.

The hexagonal boron nitride can be contained in the composite in an amount sufficient to provide the composite suitable thermal conductivity, dielectric constant, and mechanical properties. The hexagonal boron nitride can be present in the composite in an amount of 1 to 90 wt %, or 1 to 85 wt %, or 5 to 80 wt %, or 1 to 20 wt % based on a total weight of the composite. The composite can have a thermal conductivity of 1 W/m·K or more, or of 2 W/m·K or more, or 4 W/m·K or more, or 1 to 50 W/m·K measured according to ASTM D5470-12. The composite can have a dielectric constant of 1.5 to 15, or 3 to 12, or 4 to 10, measured, for example, at room temperature at 5.75×10⁹ Hz. The composite can have a coefficient of thermal expansion of 1 to 50 parts per million per degree Celsius (ppm/° C.), or 2 to 40 ppm/° C., or 4 to 30 ppm/° C., for example, determined in accordance with ASTM E831-06 or ASTM D3386-00 at −125 to 20° C. using a 1 mil (0.0254 millimeter) thick sample.

The composite can further comprise an additional filler, for example, a filler to adjust the dielectric properties of the composite. A low coefficient of expansion filler, for example, at least one of glass beads, silica, or ground micro-glass fibers, can be used. A thermally stable fiber, for example, an aromatic polyamide or a polyacrylonitrile, can be used. Representative fillers include titanium dioxide (rutile and anatase), barium titanate (BaTiO₃), Ba₂Ti₉O₂₀, strontium titanate, fused amorphous silica, corundum, wollastonite, aramide fibers (for example KEVLAR™ from DuPont), fiberglass, quartz, aluminum nitride, silicon carbide, beryllia, alumina, magnesia, mica, talcs, nanoclays, aluminosilicates (natural and synthetic), or fumed silicon dioxide (for example Cab-O-Sil, available from Cabot Corporation), each of which can be used alone or in combination.

The hexagonal boron nitride can be used in thermal management applications, for example, in a thermal management assembly. The thermal management assembly can comprise the composite material, wherein the composite material is in contact with at least one external heat transfer surface to conduct heat away from the at least one external heat transfer surface. The composite material can be disposed between an external surface of a heat-generating member and an external surface of a heat-dissipative member to provide a thermally conductive transfer there between. The heat-generating member can be an electronic component or circuit board, and the heat dissipative member can be a heat sink or circuit board.

An article can comprise the hexagonal boron nitride. The article can be for use in a sewage treatment application, a military application, or an aviation application.

In an aspect, the present method is a method for preparing hexagonal boron nitride by a carbothermal reduction and nitridation reaction, in particular a process for preparing hexagonal boron nitride in a one-step reaction using a template method, in the field of inorganic non-metallic powder materials. The method can comprise: (1) a boron compound, carbon template, and an organic solvent are mixed in a given ratio and stirred, then dried by evaporation to obtain a mixture of a boron compound and the carbon template; (2) the mixture obtained in (1) is put into a graphite crucible, and undergoes a nitriding reaction by carbothermal reduction in flowing nitrogen for 1 to 10 hours; and (3) surplus carbon is removed from the product obtained in (2), to finally obtain a hexagonal boron nitride that reflects the size, shape, and morphology of the carbon template.

An innovative feature of the present disclosure is that a carbon template can be used as a template and a reactant, and a carbothermal reduction and nitridation reaction can be used, with the assistance of a suitable dispersant and a rational heating process, to prepare pure hexagonal boron nitride efficiently in one reaction step. The use of a suitable dispersant can ensure high solubility of the boron compound to maintain good dispersion of the carbon template, thereby enabling the boron compound and the carbon template to mix uniformly, while maintaining good infiltration therebetween. A carbon template can be used as a starting material; not only can this serve as a carbon source for the carbothermal reduction and nitridation reaction, but the carbon template can also be used as a template for an in-situ nitriding reaction by carbothermal reduction to produce hexagonal boron nitride.

The present method is a simple and efficient process, using inexpensive starting materials. The hexagonal boron nitride prepared can be puffy and porous, having a large specific surface area. The use of an organic solvent as a dispersant during the mixing can not only ensure uniform mixing of the boron compound with the carbon template, but the organic solvent can be removed by heating in a low-temperature oven, thereby eliminating the need for complex downstream processes for the isolation and removal of impurities used in other preparation methods.

The present method can use an excess of carbon template in order to ensure that there is no residual boron compound in the crude product, and surplus carbon template can be removed completely by a simple one-step process for removing carbon by heating, to produce hexagonal boron nitride of high purity.

The present method can use a heating system during the carbothermal reduction and nitridation reaction, to ensuring that the boron compound can react directly and completely with the carbon template and the nitrogen, so that the product conversion rate is high.

The starting materials employed, for example, the carbon template, the boron compound, and organic solvent, are readily available and inexpensive, so the cost of industrial production can be reduced, facilitating mass industrial production of pure boron nitride.

The following examples are provided to illustrate articles with enhanced thermal capability. The examples are merely illustrative and are not intended to limit devices made in accordance with the disclosure to the materials, conditions, or process parameters set forth therein. Obviously, the examples described are merely some, not all, of the examples of the present disclosure. All other examples obtained by those skilled in the art on the basis of the examples in the present disclosure, without making any inventive effort, are included in the scope of protection of the present disclosure. The following examples, and features therein, may be combined with each other where no conflict arises.

### EXAMPLES

In the examples, an X-ray diffractometer was used to analyze the hexagonal boron nitride, and a scanning electron microscope is used to observe the morphology of the hexagonal boron nitride.

### Example 1

### Preparation of a Hexagonal Boron Nitride Nanofiber

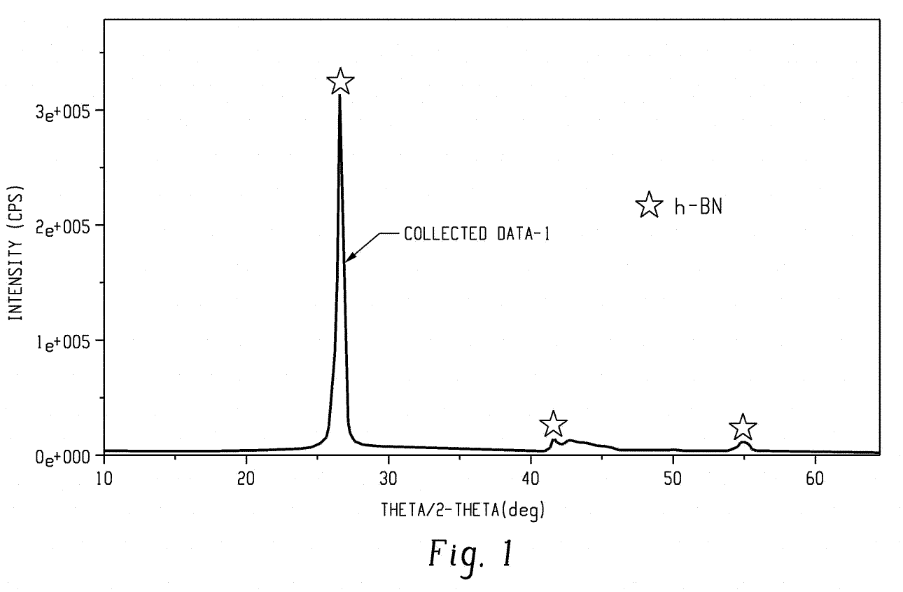

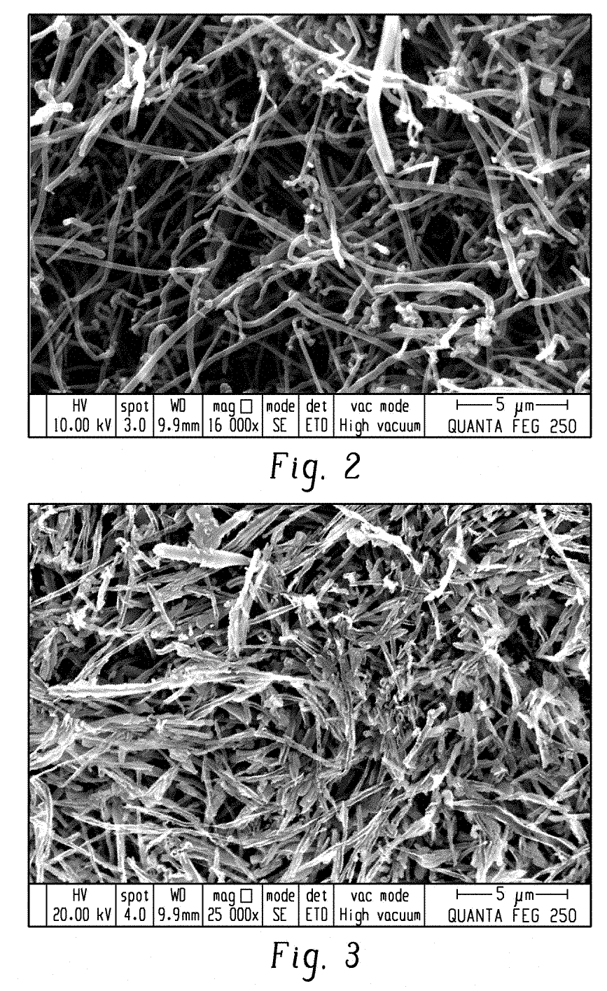

A mixture was formed by dissolving 14 g of boric acid in 50 mL of methanol and then adding 2 g of carbon nanofibers having an average diameter of 200 nm and an average length of 15 micrometers. The mixture was stirred using a magnetic stir bar for 1 hour. After stirring, the stirred viscous liquid mixture was put in an oven at 80° C. for 6 hours to dry, to obtain a dried mixture of the boron compound and the carbon nanofibers. The dried mixture was then spread flat in a graphite crucible, and put into a tubular furnace. At an Na flow rate of 80 mL/min, the tubular furnace was heated to a first temperature of 200° C. at the rate of 10° C./min and held at this first temperature for 0.5 hours, then heated to a second temperature of 900° C. at a rate of 10° C./min and held at this second temperature for 1 hour, then heated to a third temperature of 1,550° C. at a rate of 5° C./min and held at this third temperature for 6 hours, and finally cooled to room temperature. Once the reaction was complete, the crude product obtained was put into a muffle furnace and held at a temperature of 700° C. for 6 hours to remove surplus carbon and to finally obtain hexagonal boron nitride nanofibers having an average diameter of 250 nm and an average length of 10 micrometers. The X-ray diffraction spectrum for the hexagonal boron nitride is illustrated in FIG. 1. An SEM image of the initial carbon nanofibers is shown in FIG. 2 and an SEM image of the boron nitride nanofibers is shown in FIG. 3.

Set forth below are non-limiting aspects of the present disclosure.

Aspect 1: A method for preparing hexagonal boron nitride, comprising: mixing a boron compound and a carbon template in an organic solvent to form a mixture; wherein the carbon template comprises a plurality of carbon fibers, a plurality of carbon nanotubes, activated carbon, a plurality of graphite films, a plurality of graphene sheets, or a combination comprising at least one of the foregoing; removing the organic solvent to provide a dried mixture of the boron compound and the carbon template; exposing the dried mixture to a nitrogen-containing gas under conditions effective to provide a crude product comprising hexagonal boron nitride; removing the carbon template from the crude product to provide the hexagonal boron nitride in the form of a plurality of boron nitride fibers, a plurality of boron nitride nanotubes, an activated boron nitride, a plurality of boron nitride films, a plurality of boron nitride sheet, or a combination comprising at least one of the foregoing.

Aspect 2: The method of any one or more of the preceding aspects, wherein the boron compound comprises an amine pentaborate, a boric ester, borax, boric acid or a salt thereof, pyroboric acid or a salt thereof, tetraboric acid or a salt thereof, boron oxide, or a combination comprising one or more of the foregoing.

Aspect 3: The method of any one or more of the preceding aspects, wherein the carbon template comprises a surface treated carbon template comprising a plurality of one or both of hydroxyl or carboxyl functional groups.

Aspect 4: The method of any one or more of the preceding aspects, wherein the organic solvent comprises ethanol, methanol, glycerin, a polyether, polypropanol, or a combination comprising one or more of the foregoing.

Aspect 5: The method of any one or more of the preceding aspects, wherein the mixing occurs at a temperature of 0 to 60° C.

Aspect 6: The method of any one or more of the preceding aspects, wherein the mixing occurs for 0.5 to 10 hours.

Aspect 7: The method of any one or more of the preceding aspects, wherein the mixing comprises at least one of mixing for greater than or equal to 2 hours, ultrasonically vibrating during mixing, and wet ball mixing.

Aspect 8: The method of any one or more of the preceding aspects, wherein the mixture comprises 5 to 200 mL, or 5 to 25 mL, or 5 to 15 mL, or 25 to 200 mL of the organic solvent per 1 g of the total of the boron compound and the carbon template.

Aspect 9: The method of any one or more of the preceding aspects, wherein the removing the organic solvent comprises heating the mixture, applying a vacuum pressure to the mixture, freeze-drying the mixture, or a combination of one or more of the foregoing.

Aspect 10: The method of any one or more of the preceding aspects, wherein the dry mixture comprises less than or equal to 1 mL, or 0 to 0.1 mL of the organic solvent per 1 g of the total of the boron compound and the carbon template.

Aspect 11: The method of any one or more of the preceding aspects, wherein the molar ratio of carbon template to boron compound in the mixture is 1:0.2 to 1:2.

Aspect 12: The method of any one or more of the preceding aspects, further comprising spreading the dried mixture in a graphite crucible prior to the exposing.

Aspect 13: The method of any one or more of the preceding aspects, wherein the exposing occurs for 1 to 10 hours.

Aspect 14: The method of any one or more of the preceding aspects, wherein the exposing comprises flowing nitrogen gas at a flow rate of 40 to 1,000 ml/min, or 60 to 200 mL/min

Aspect 15: The method of any one or more of the preceding aspects, wherein the exposing comprises: heating the dry mixture to a first temperature of 100 to 500° C. at a rate of 3 to 10° C./min; maintaining the first temperature for 0.5 to 3 hours; heating to a second temperature of 700 to 1,100° C. at a rate of 3 to 10° C./min; maintaining the second temperature for 0.5 to 3 hours; heating to a third temperature of 1,200 to 1,700° C. at a rate of 3 to 10° C./min; and maintaining the third temperature for 0.5 to 3 hours.

Aspect 16: The method of any one or more of the preceding aspects, wherein the removing the carbon template from the crude product to provide the hexagonal boron nitride comprises heating in the presence of oxygen.

Aspect 17: The method of any one or more of the preceding aspects, further comprising mixing the hexagonal boron nitride with a polymer to form a polymer composite material.

Aspect 18: The method of any one or more of the preceding aspects, wherein the carbon template comprises the plurality of carbon fibers, the plurality of carbon nanotubes, the activated carbon, or a combination comprising at least one of the foregoing; and wherein the hexagonal boron nitride in the form of a plurality of boron nitride fibers, a plurality of boron nitride nanotubes, an activated boron nitride, or a combination comprising at least one of the foregoing.

Aspect 19: A hexagonal boron nitride prepared by any one or more of the foregoing aspects.

Aspect 20: The hexagonal boron nitride of Aspect 19, wherein the hexagonal boron nitride comprises the plurality of boron nitride fibers, the plurality of boron nitride nanotubes, or a combination comprising at least one of the foregoing.

Aspect 21: A composite material comprising, a polymer matrix; and the hexagonal boron nitride of any one or more of the preceding aspects dispersed in the polymer matrix.

Aspect 22: The composite material of Aspect 21, wherein the composite material has a first and a second heat transfer surface.

Aspect 23: The composite material of any one or more of aspects 21 to 22, comprising 1 to 90 weight percent, or 5 to 80 weight percent, or 1 to 20 weight percent of the boron nitride filler, based on the total weight of the composite material.

Aspect 24: The composite material of any one or more of aspects 21 to 23, wherein the composite material has an average thickness of 0.01 to 25 millimeters, or 0.1 to 25 millimeters.

Aspect 25: The composite material of any one or more of aspects 21 to 24, wherein the polymer matrix comprises polyurethane, silicone, polyolefin, polyester, polyamide, fluorinated polymer, polyalkylene oxide, polyvinyl alcohol, ionomer, cellulose acetate, polystyrene, a polyamideimide, an epoxy resin, or a combination comprising at least one of the foregoing.

Aspect 26: The composite material of any one or more of aspects 21 to 25, wherein the polymer matrix is a compressible foam.

Aspect 27: A thermal management assembly comprising the composite material of one or more of Aspects 21 to 26, wherein the composite material is in contact with at least one external heat transfer surface to conduct heat away from the at least one external heat transfer surface.

Aspect 28: The thermal management assembly of Aspect 27, wherein the composite material is disposed between an external surface of a heat-generating member and an external surface of a heat-dissipative member to provide a thermally conductive transfer there between.

Aspect 29: The thermal management assembly of Aspect 28, wherein the heat-generating member is an electronic component or circuit board, and the heat dissipative member is a heat sink or circuit board.

Aspect 30: An article comprising the hexagonal boron nitride of any one or more of the preceding aspects.

Aspect 31: The article of Aspect 30, wherein the article is for use in a sewage treatment application, a military application, or an aviation application.

Aspect 32: The method of any one or more of the foregoing, wherein the mixing is conducted in the presence of a dispersant, preferably an anionic surfactant, more preferably sodium dodecyl sulfate.

The compositions, methods, and articles can alternatively comprise, consist of, or consist essentially of, any appropriate materials, steps, or components herein disclosed. The compositions, methods, and articles can additionally, or alternatively, be formulated so as to be devoid, or substantially free, of any materials (or species), steps, or components, that are otherwise not necessary to the achievement of the function or objectives of the compositions, methods, and articles.

The terms “a” and “an” do not denote a limitation of quantity, but rather denote the presence of at least one of the referenced item. The term “or” means “and/or” unless clearly indicated otherwise by context. Reference throughout the specification to “an aspect”, “an embodiment”, “another embodiment”, “some embodiments”, and so forth, means that a particular element (e.g., feature, structure, step, or characteristic) described in connection with the embodiment is included in at least one embodiment described herein, and may or may not be present in other embodiments. In addition, it is to be understood that the described elements may be combined in any suitable manner in the various embodiments.

In general, the compositions, methods, and articles can alternatively comprise, consist of, or consist essentially of, any ingredients, steps, or components herein disclosed. The compositions, methods, and articles can additionally, or alternatively, be formulated, conducted, or manufactured so as to be devoid, or substantially free, of any ingredients, steps, or components not necessary to the achievement of the function or objectives of the present claims.

Unless specified to the contrary herein, all test standards are the most recent standard in effect as of the filing date of this application, or, if priority is claimed, the filing date of the earliest priority application in which the test standard appears.

The endpoints of all ranges directed to the same component or property are inclusive of the endpoints, are independently combinable, and include all intermediate points and ranges. For example, ranges of “up to 25 wt %, or 5 to 20 wt %” is inclusive of the endpoints and all intermediate values of the ranges of “5 to 25 wt %,” such as 10 to 23 wt %, etc.

The term “combination” is inclusive of blends, mixtures, alloys, reaction products, and the like. Also, “combinations comprising at least one of the foregoing” and “at least one of” means that the list is inclusive of each element individually, as well as combinations of two or more elements of the list, and combinations of at least one element of the list with like elements not named

Unless defined otherwise, technical and scientific terms used herein have the same meaning as is commonly understood by one of skill in the art to which this disclosure belongs.

All cited patents, patent applications, and other references are incorporated herein by reference in their entirety. However, if a term in the present application contradicts or conflicts with a term in the incorporated reference, the term from the present application takes precedence over the conflicting term from the incorporated reference.

While particular aspects have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

What is claimed is:

1. A method for preparing hexagonal boron nitride, the method comprising:
mixing a boron compound and a carbon template in an organic solvent to form a mixture;
wherein the carbon template comprises a plurality of carbon fibers, a plurality of carbon nanotubes, activated carbon, a plurality of graphite films, a plurality of graphene sheets, or a combination comprising at least one of the foregoing;
removing the organic solvent to provide a dried mixture of the boron compound and the carbon template;
exposing the dried mixture to a nitrogen-containing gas under conditions effective to provide a crude product comprising hexagonal boron nitride;
removing the carbon template from the crude product to provide the hexagonal boron nitride in the form of a plurality of boron nitride fibers, a plurality of boron nitride nanotubes, an activated boron nitride, a plurality of boron nitride films, a plurality of boron nitride sheet, or a combination comprising at least one of the foregoing.

2. The method of claim 1, wherein the carbon template comprises the plurality of carbon fibers, the plurality of carbon nanotubes, the activated carbon, or a combination comprising at least one of the foregoing.

3. The method of claim 1, wherein the boron compound comprises an amine pentaborate, a boric ester, borax, boric acid or a salt thereof, pyroboric acid or a salt thereof, tetraboric acid or a salt thereof, boron oxide, or a combination comprising one or more of the foregoing.

4. The method of claim 1, wherein the organic solvent comprises ethanol, methanol, glycerin, a polyether, or a combination comprising one or more of the foregoing.

5. The method of claim 1, wherein the mixture comprises 5 to 200 milliliters of the organic solvent per 1 gram of the total of the boron compound and the carbon template.

6. The method of claim 1, wherein the removing the organic solvent comprises heating the mixture, applying a vacuum pressure to the mixture, freeze-drying the mixture, or a combination of one or more of the foregoing.

7. The method of claim 1, wherein the molar ratio of carbon template to boron compound in the mixture is 1:0.2 to 1:2.

8. The method of claim 1, further comprising spreading the dried mixture in a graphite crucible prior to the exposing.

9. The method of claim 1, wherein the exposing occurs for 1 to 10 hours.

10. The method of claim 1, wherein the exposing comprises flowing nitrogen gas at a flow rate of 40 to 1,000 milliliters per minute.

11. The method of claim 1, wherein the exposing comprises:
heating the dry mixture to a first temperature of 100 to 500 degrees Celsius at a rate of 3 to 10 degrees Celsius per minute;
maintaining the first temperature for 0.5 to 3 hours;
heating to a second temperature of 700 to 1,100 degrees Celsius at a rate of 3 to 10 degrees Celsius per minute;
maintaining the second temperature for 0.5 to 3 hours;
heating to a third temperature of 1,200 to 1,700 degrees Celsius at a rate of 3 to 10 degrees Celsius per minute; and
maintaining the third temperature for 0.5 to 3 hours.

12. The method of claim 1, wherein the removing the carbon template from the crude product to provide the hexagonal boron nitride comprises heating in the presence of oxygen.

13. The method of claim 1, further comprising mixing the hexagonal boron nitride with a polymer to form a polymer composite material.

14. A hexagonal boron nitride prepared by the method of claim 1.

15. A composite material comprising a polymer matrix and the hexagonal boron nitride of claim 1 dispersed in the polymer matrix.

16. The composite material of claim 15, wherein the composite material has an average thickness of 0.01 to 25 millimeters.

17. The composite material of claim 15, wherein the polymer matrix comprises a polyurethane, a silicone polymer, a polyolefin, a polyester, a polyamide, a fluorinated polymer, a polyalkylene oxide, polyvinyl alcohol, an ionomer, cellulose acetate, a polystyrene, a polyamideimide, an epoxy resin, or a combination comprising at least one of the foregoing.

18. The composite material of claim 15, wherein the polymer matrix is a compressible foam.

19. A thermal management assembly comprising the composite material of claim 15, wherein the composite material is in contact with at least one external heat transfer surface to conduct heat away from the at least one external heat transfer surface.

20. The thermal management assembly of claim 19, wherein the composite material is disposed between an external surface of a heat-generating member and an external surface of a heat-dissipative member to provide a thermally conductive transfer there between.
